(19) United States
(12) Patent Application Publication
(10) Pub. No.: US 2003/0000476 A1
(43) Pub. Date: Jan. 2, 2003

(54) Substrate processing apparatus, conveying unit thereof, and semiconductor device fabricating Method

(75) Inventors: Tatsuhisa Matsunaga, Tokyo (JP); Hiroshi Sekiyama, Tokyo (JP)

Correspondence Address: Eugene Mar, BACON & THOMAS, 625 Slaters Lane - 4th Floor, Alexandria, VA, 22314, US

(73) Assignee: Hitachi Kokusai Electric Inc., Tokyo (JP)

(21) Appl. No.: 10/106,200

(22) Filed: Mar. 27, 2002

(30) Foreign Application Priority Data
Jun. 28, 2001 (JP) 2001-196539

(51) Int. Cl. C23C 16/00

(52) U.S. Cl. 118/719; 118/729; 118/715; 118/733

(57) ABSTRACT

A substrate processing apparatus includes a process chamber, a sealed chamber arranged, a movable member disposed inside the sealed chamber, an extendable/contractible structure having a first and a second extendable/contractible member respectively disposed on both opposing sides of the movable member, and a driving mechanism, disposed in the extendable/contractible structure, for driving the movable member. The driving mechanism is isolated from an inner surface of the sealed chamber. The interiors of the first and the second extendable/contractible member communicate with an exterior of the sealed chamber.

### FIELD OF THE INVENTION

The present invention relates to a substrate processing apparatus, conveying unit thereof, and a semiconductor device fabricating method using the apparatus; and, more particularly, to a conveying unit for use in a sealing chamber of a substrate processing apparatus, and a semiconductor device fabricating method using the apparatus.

### BACKGROUND OF THE INVENTION

Generally, a substrate processing apparatus is used to form a chemical vapor deposition (CVD) film, such as an insulating film or a metal film, on a semiconductor wafer or to diffuse impurities onto the wafer.

There is provided a conventional substrate processing apparatus in the U.S. Pat. No. 5,571,330, which discloses a load lock chamber for a vertical type heat treatment apparatus. The load lock chamber is arranged below a treatment chamber of the vertical type heat treatment apparatus, and can load, under a gas proof condition, a boat for placing wafers into the treatment chamber and unload the boat therefrom through a lower part of the treatment chamber.

The load lock chamber is formed by a vertically extendible/contractible hollow structure including a first and a second bellows, having different sizes, and a connecting member therebetween. The first and the second bellows are telescopically nested in the connecting member when the hollow structure is maximally contracted. The open upper end of the hollow structure is hermetically coupled with the treatment chamber located thereabove, while the lower end thereof is airtightly closed by a movable member on which the boat is mounted. The connecting member and the movable member are engaged with an elevator mechanism located outside the hollow structure so that the boat mounted inside the hollow structure can be driven to move up and down by the elevator mechanism hermetically isolated therefrom.

The above-mentioned load lock chamber for the vertical type heat treatment apparatus, however, has a critical deficiency. If the vertical type heat treatment apparatus processes a wafer having a diameter of 300 mm, the diameters of the first and the second bellows need to be larger than 400 mm and 500 mm both inclusive, respectively. In that case, whenever the first and the second bellows are in a vacuum state, forces of about 2000 kgf (about 20000 N) and 1200 kgf (about 12000 N) respectively act on the first and the second bellows because of a pressure difference between the atmospheric pressure (1 kgf/cm², or about 98 kPa) and the vacuum pressure of each bellows. As a result, when the wafer processed by the vertical type heat treatment apparatus has the diameter of 300 mm, a very large-sized drive mechanism should be employed to drive a vertically extending/contracting mechanism of the load lock chamber.

Japanese Patent Laid-Open Publication No. P10-181870 discloses a hermetically enclosed conveyor of a different type for use in a conventional substrate processing apparatus. The hermetically enclosed conveyor includes a supporter contained in a sealed enclosure to support an article, and a drive mechanism for driving the supporter. The sealed enclosure includes a conveying space and a drive mechanism housing space, in which an electric wiring is laid. The two spaces are hermetically separated from each other by means of a first bellows and a second bellows, such that the pressure in the conveying space and that in the drive mechanism housing space are individually controlled.

It can be contemplated to employ the above-mentioned hermetically enclosed conveyor for a boat elevator mechanism that vertically moves a boat in the vertical type heat treatment apparatus. In that case, however, the inner pressures of the first and the second bellows need to be controlled based on a pressure variation inside the load lock chamber for the purposes of: protecting the first and the second bellows from a possible deformation thereof resulting from the pressure difference between the inside and the outside of each bellows; and individually contracting or extending the first and the second bellows. In order to achieve the above-mentioned purposes, however, a complicated pressure control valve system and a control system thereof should be employed.

### SUMMARY OF THE INVENTION

It is, therefore, a primary object of the present invention to provide a substrate processing apparatus having a boat elevator mechanism of an economic size, such that a simple control scheme can be adopted therefor.

In one aspect of the present invention, there is provided a substrate processing apparatus, which includes: a process chamber for processing substrates; a sealed chamber arranged adjacent to the process chamber; a movable member, disposed inside the sealed chamber, for supporting the substrates; an extendable/contractible structure including a first extendable/contractible member and a second extendable/contractible member respectively disposed on both opposing sides of the movable member, wherein interiors of the first and the second extendable/contractible member communicate with an exterior of the sealed chamber; and a driving means, disposed in the extendable/contractible structure, for moving the movable member, wherein the driving means is isolated from an inner space of the sealed chamber by the extendable/contractible structure.

In another aspect of the present invention, there is provided a semiconductor device fabricating method using a substrate processing apparatus including a sealed chamber, a process chamber, and a substrate conveying unit positioned in the sealed chamber, wherein the substrate conveying unit includes a) a movable member for supporting a boat, b) a first and a second extendible/contractible member respectively disposed on both opposing sides of the movable member, interiors of the first and the second extendible/contractible member communicating with an exterior circumstance, and c) a driving means, disposed in the first and the second extendible/contractible member, for moving the movable member, the driving means being isolated from an inner space of the sealed chamber by the first and the second extendible/contractible member, the method including the steps of: loading at least one substrate into the boat staying in the sealed chamber; loading the boat into the process chamber from the sealed chamber by using the substrate conveying unit; and processing said at least one substrate loaded in the boat.

In another aspect of the present invention, there is provided a conveying unit used in a sealed chamber, the conveying unit including: a movable member arranged in the sealed chamber, the movable member supporting an article; a first extendible/contractible structure and a second extendible/contractible structure respectively disposed on both opposing sides of the movable member, wherein interiors of the first and the second extendible/contractible structure individually communicate with an exterior of the sealed chamber; and a driving means, disposed in the first and the second extendible/contractible structure, for moving the movable member, wherein the driving means is isolated from an inner space of the sealed chamber by the first and the second extendible/contractible structure

### BRIEF DESCRIPTION OF THE DRAWINGS

The above and other objects and features of the present invention will become apparent from the following description of preferred embodiments given in conjunction with the accompanying drawings, in which:

FIG. 1 presents a sectional plan view of a batch type CVD apparatus in accordance with a preferred embodiment of the present invention;

FIG. 2 is a sectional side view taken along a line II-II of FIG. 1;

FIG. 3 represents a sectional side view taken along another line III-III of FIG. 1;

FIG. 4 depicts a partial extended side view of a boat elevator;

FIG. 5A shows a sectional view taken along a line a-a of FIG. 4;

FIG. 5B describes a sectional view taken along a line b-b of FIG. 4;

FIG. 5C provides a sectional view taken along a line c-c of FIG. 4;

FIG. 5D illustrates a sectional view that corresponds to FIG. 5B, in accordance with another preferred embodiment of the present invention;

FIG. 6 sets forth a sectional side view showing a process stage in which a boat is loaded into a process chamber; and

FIG. 7 gives a sectional rear view of FIG. 6.

### DETAILED DESCRIPTION OF THE PREFERRED EMBODIMENT

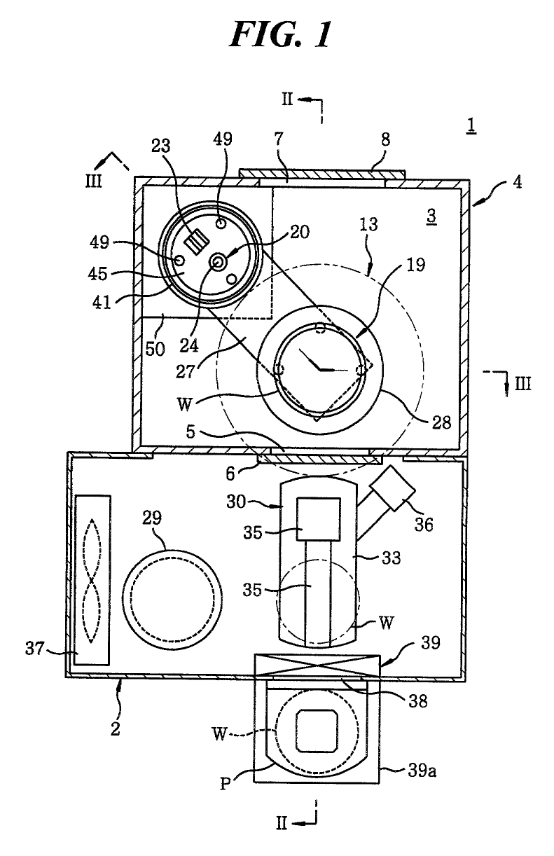

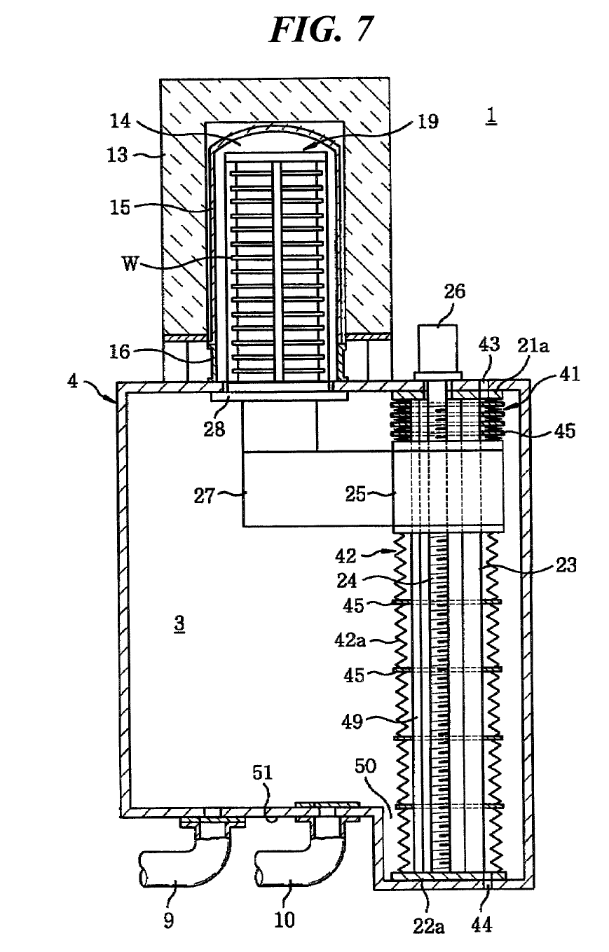

Referring now to FIGS. 1 to 7, a substrate processing apparatus in accordance with preferred embodiments of the present invention will be described in detail. Like numerals represent like parts in the drawings.

The substrate processing apparatus in accordance with the preferred embodiments is a batch type vertical diffusion/CVD apparatus 1 (referred to as a batch type CVD apparatus hereinafter), which is adapted for use in a CVD process for forming a CVD film, e.g., an insulating film or a metal film on a wafer or an impurity diffusion process for diffusing impurities onto the wafer. The batch type CVD apparatus 1 adopts a front opening unified pod (FOUP, referred to as a pod hereinafter) for a wafer conveying carrier.

In the following descriptions, a front, a rear, a left and a right side are defined on the basis of parts shown in FIG. 1. That is to say, the front side refers to where a pod opener 39 is positioned; the rear side, a load lock chamber 4; the left side, a clean air unit 37; and finally the right side, an elevator 36 of a wafer transfer unit 30.

As shown in FIGS. 1 to 3, the batch type CVD apparatus 1 includes a housing 2. Disposed at the rear side of the housing 2 is the load lock chamber 4 that forms therein an antechamber 3, where a boat 19 is located. The antechamber 3 is a sealed enclosure capable of maintaining therein a sub-atmospheric pressure. The load lock chamber 4 is of a shape of an approximately rectangular box large enough to accommodate therein the boat 19. Formed through a front wall of the load lock chamber 4 is a wafer loading/unloading opening 5, which is selectively opened or closed by a gate 6.

Formed through a rear wall of the load lock chamber 4 is a repair/inspection opening 7. For a repair or inspection, the boat 19 is loaded into or unloaded from the antechamber 3 through the repair/inspection opening 7, which is usually closed by another gate 8 except for the repair or inspection time.

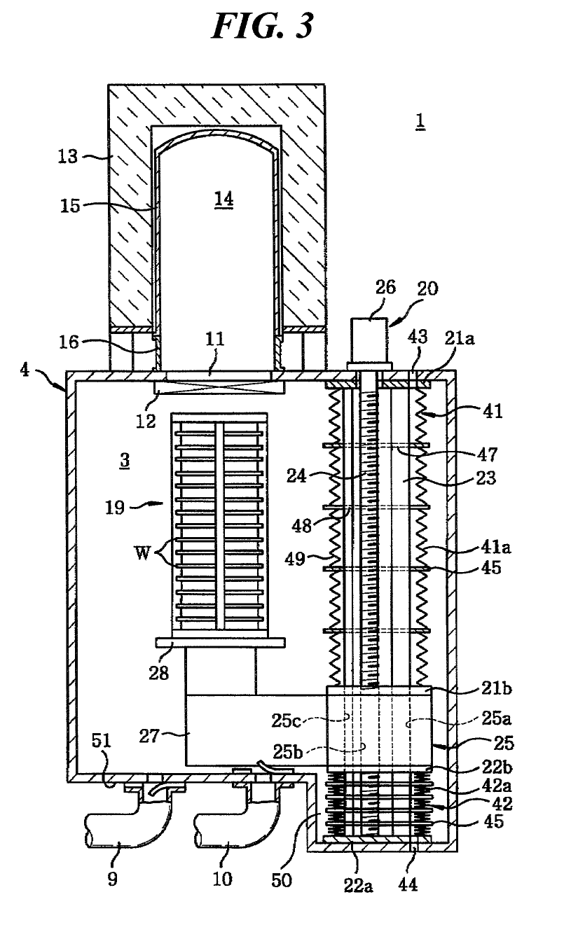

As shown in FIG. 3, an exhaust line 9 and a gas supply line 10 are individually connected to a bottom wall of the load lock chamber 4. The exhaust line 9 serves to exhaust the antechamber 3 such that the inner pressure thereof reduces below the atmospheric pressure. Nitrogen (N2) gas is introduced into the antechamber 3 through the gas supply line 10, whenever it is needed.

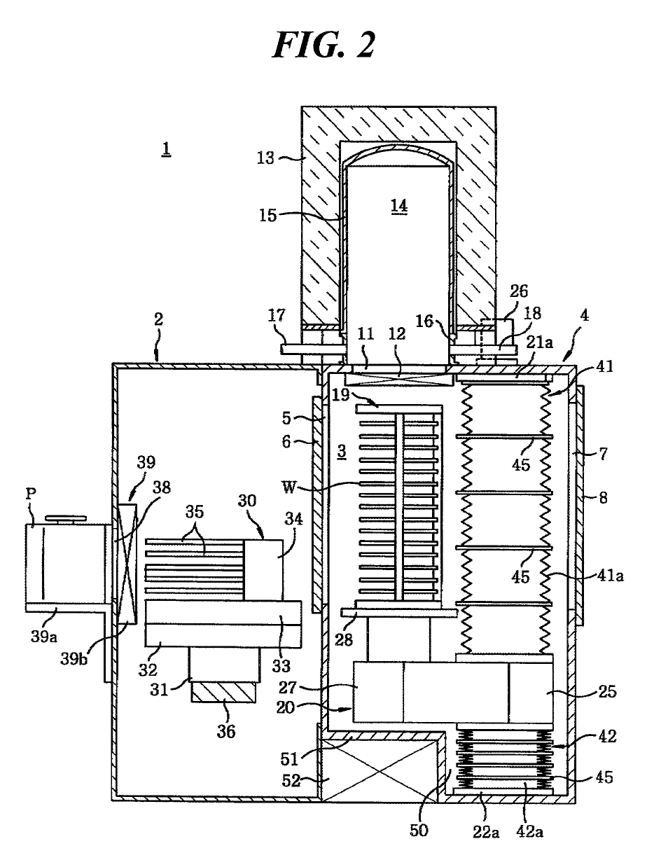

As shown in FIGS. 2 and 3, a boat loading/unloading opening 11, which is selectively opened or closed by a shutter 12, is formed in a ceiling wall of the load lock chamber 4. A heater unit 13 is vertically arranged on the load lock chamber 4, and a process tube 15 having a process chamber 14 formed in the hollow space therein is arranged inside the heater unit 13. The process tube 15 is of a cylindrical shape having a closed upper portion and an opened lower portion and is concentrically arranged with the heater unit 13 therein.

The process tube 15 is supported by a manifold 16 located on the ceiling wall of the load lock chamber 4 and a gas supply line 17 and an exhaust line 18 are connected to the manifold 16, wherein source gas or purge gas is introduced into the process chamber 14 through the gas supply line 17, and the process tube 15 is exhausted through the exhaust line 18. The manifold 16 is concentrically arranged with the boat loading/unloading opening 11 of the load lock chamber 4.

Arranged at a rear left side of the antechamber 3 is a conveying unit or a boat elevator 20 serving to vertically move the boat 19. The boat elevator 20 includes a main guide rail 23 and a feed screw 24, which are vertically arranged between an upper installation plate 21a and a lower installation plate 22a. The main guide rail 23 guides an elevator stage 25 serving as a mover. The elevator stage 25 is screw-coupled with the feed screw 24, such that the elevator stage 25 can move up or down along the main guide rail 23 while the feed screw 24 are rotating.

For facilitating a smooth operation and a proper backlash, a ball screw mechanism is preferably applied to the coupling of the feed screw 24 and the elevator stage 25. An upper edge portion of the feed screw 24 sequentially passes through the upper installation plate 21a and the ceiling wall of the load lock chamber 4, finally projecting from the top of the antechamber 3. A motor 26 installed outside the antechamber 3 is coupled to the upper edge portion of the feed screw 24, thereby rotating the feed screw 24 either clockwise or counterclockwise.

An arm 27 horizontally protrudes from a side of the elevator stage 25, and a sealing cap 28 running parallel to the arm 27 is arranged on a vertically protruding member provided at an edge portion of the arm 27. The sealing cap 28 vertically supports the boat 19 and functions to airtightly close the boat loading/unloading opening 11 serving as a furnace mouth of the process tube 15. The boat 19 concentrically accommodates a multiplicity of wafers “W” (for example, 25, 50, 100, 125, or 150 wafers). Then, the boat 19 is loaded into or unloaded from the process chamber 14 of the process tube 15 in accordance as the sealing cap 28 is elevated or descended by the boat elevator 20.

As shown in FIGS. 1 and 2, the wafer transfer unit 30 arranged inside the housing 2 is configured to transfer the wafers “W”. The wafer transfer unit 30 has a rotary actuator 31, which drives a first linear actuator 32 installed thereon such that the first linear actuator 32 can rotate on a horizontal plane. A second linear actuator 33 is installed on the first linear actuator 32, which horizontally moves the second linear actuator 33. A moving stage 34 is installed on the second linear actuator 33, which horizontally moves the moving stage 34.

On the moving stage 34, a number of horizontal tweezers 35 (5 pairs in this preferred embodiment) are arranged with an equal pitch therebetween. Each pair of the tweezers 35 serves to support the wafers “W” disposed thereon. The wafer transfer unit 30 is elevated or descended by the elevator 36 having a feed screw mechanism or the like. The clean air unit 37 is arranged opposite to the elevator 36. Further, a reference numeral 29 of FIG. 1 refers to a notch coupling unit.

As shown in FIGS. 1 and 2, another wafer loading/unloading opening 38 is formed through a front wall of the housing 2 so that wafers can be loaded into or unloaded from the housing 2 therethrough. The pod opener 39 is arranged at the wafer loading/unloading opening 38. The pod opener 39 has a loading stage 39a for mounting a pod “P” thereon and a cap device 39b. The cap device 39b serves to remove or restore the cap of the pod “P” mounted on a loading stage 22, thereby opening or closing a wafer-way of the pod “P”. The pod “P” is supplied to or removed from the loading stage 39a by means of a pod conveying system (not shown), such as a rail guided vehicle (RGV).

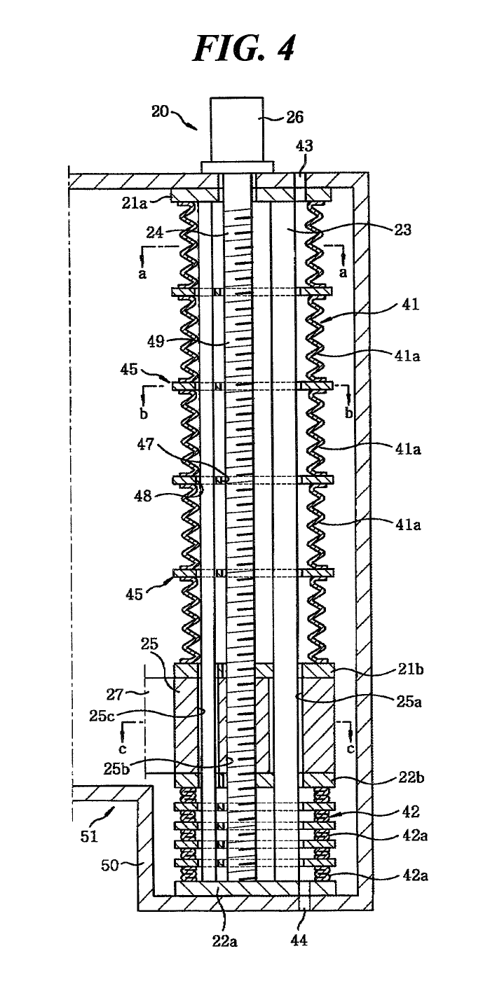

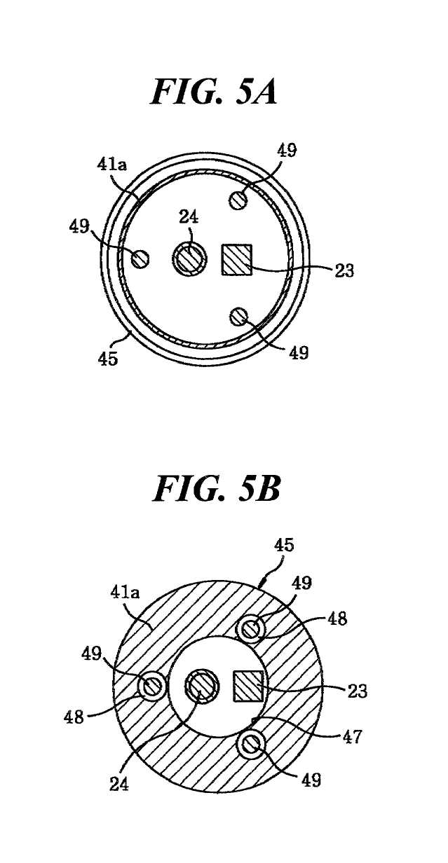

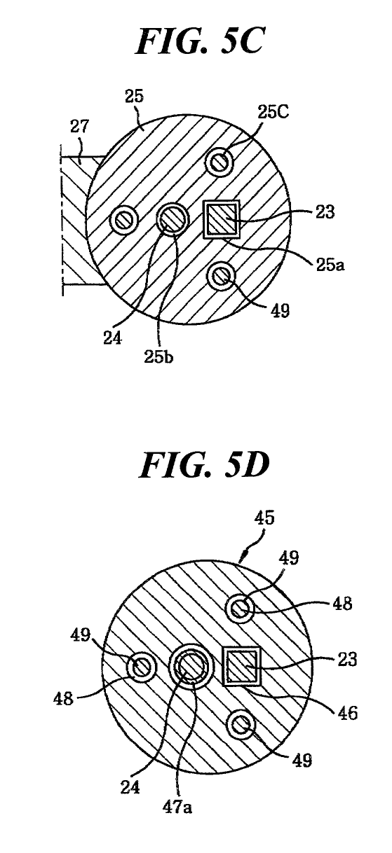

In accordance with a preferred embodiment illustrated in detail with reference to FIGS. 4 to 5D, a first bellows 41 as a first extendable/contractible structure and a second bellows 42 as a second extendable/contractible structure are respectively arranged on top and bottom of the elevator stage 25, wherein the main guide rail 23 as well as the feed screw 24 is accommodated in the vertically extended inner space defined by the first and the second bellows 41 and 42. The inner spaces of the first and the second bellows 41 and 42 are hermitically isolated from that of the load lock chamber 4.

A first communicating hole 43 is formed through the ceiling wall of the load lock chamber 4 and the upper installation plate 21a. A second communicating hole 44 is also formed through the bottom wall of the load lock chamber 4 as well as the lower installation plate 22a. The first and the second communicating hole 43 and 44 make the inner spaces of the first and the second bellows 41 and 42 individually communicate with the environment so that the whole inner spaces defined by the first and the second bellows 41 and 42 can be maintained at the atmospheric pressure.

Each of the first and the second bellows 41 and 42 is provided with a multiplicity of horizontal reinforcing sheets 45 (4 sheets in this preferred embodiment), which are arranged at equi-distance vertically. The reinforcing sheets 45 serve to prevent the first and the second bellows 41 and 42 from being deformed from their vertical or horizontal profile. Each reinforcing sheet 45 shown in FIG. 5A is of a shape of a thin disk having a diameter larger than those of the first and the second bellows 41 and 42 (FIG. 2). Formed through each reinforcing sheet 45 as shown in FIG. 5B are an escape hole 47 and a multiple number of guide holes 48 (3 holes in this preferred embodiment). The main guide rail 23 and the feed screw 24 pass through the escape hole 47.

Passing through the guide holes 48, a corresponding number of auxiliary guide rails 49 (3 auxiliary guide rails in this preferred embodiment) are vertically arranged between the upper and the lower installation plate 21a and 22a, inside the first and the second bellows 41 and 42. The reinforcing sheets 45 smoothly slide up and down along the auxiliary guide rails 49. Because of the auxiliary guide rails 49, the reinforcing sheets 45 can be safely guided in the vertical direction without a transversal motion.

In addition, the elevator stage 25 has a main guide hole 25a, a screw hole 25b, and auxiliary guide holes 25c. The main guide rail 23 smoothly passes through the main guide hole 25a while each auxiliary guide rails 49 smoothly passes through its corresponding auxiliary guide hole 25c. The elevator stage 25 is screw-coupled with the feed screw 24 via the screw hole 25b, a female screw. Furthermore, instead of adopting the large escape hole 47 through which the main guide rail 23 as well as the feed screw 24 passes, a major guide hole 46 for the main guide rail 23 and an escape hole 47a for the feed screw 24 may be individually formed on the reinforcing sheet 45, as shown in FIG. 5D.

By the reinforcing sheets 45, the first bellows 41 is divided into a plural of sub-bellows portions 41a (5 portions in this preferred embodiment) vertically arranged with an approximately equal length. An upper circumference of the sub-bellows portion 41a is airtightly fastened on the bottom surface of a reinforcing sheet 45 positioned thereabove, and a lower circumference thereof is airtightly fastened on the top surface of another reinforcing sheet 45 positioned therebelow. However, the upper circumference of the uppermost sub-bellows portion 41a is fastened on a bottom surface of the upper installation plate 21a, and the lower circumference of the lowermost sub-bellows portion 41a is fastened on the top surface of the other upper installation plate 21b provided on the elevator stage 25. The second bellows 42 is also divided into a multiple of sub-bellows portions 42a each being airtightly fastened to corresponding reinforcing sheets 45, the lower installation plate 22a and/or another lower installation plate 22b provided under the elevator stage 25.

A bellows-receiving portion 50 is recessed at a bottom corner of the antechamber 3, such that the bellows-receiving portion 50 can receive the second bellows 42 when the second bellows 42 is maximally contracted. That is, the other bottom corner is raised above the bellows-receiving portion 50, up to a level, e.g., just permitting the lower limit of the moving stroke of the boat 19, such that the inner space of the antechamber 3 decreases by an amount corresponding to the raised portion. As much as the peripheries of the bellows-receiving portion 50 are raised, the bottom wall of the load lock chamber 4 comes off a floor, thereby providing a space 51 therebetween. An electrical circuit box 52 as well as the exhaust line 9 and the gas supply line 10 may be disposed in the space 51.

The above-described batch type CVD apparatus is used for a semiconductor device fabricating method in accordance with the preferred embodiment. Hereinafter, there will be explained a film forming process, which is a substrate processing method constituting a part of the semiconductor device fabricating method in accordance with the preferred embodiment.

A plurality of wafers “W”, on each of which a film will be formed, are accommodated in the pod “P” and conveyed to the batch type CVD apparatus 1 by means of a conveying system (not shown). As shown in FIGS. 1 and 2, the conveyed pod “P” is mounted on the loading stage 39a. The cap of the pod “P” is subsequently removed by the cap device 39b, so that the wafer entrance of the pod “P” is opened.

After the wafer entrance of the pod “P” is opened by the pod opener 39, the tweezers 35 of the wafer transfer unit 30 disposed inside the housing 2 pick up the wafers “W” from the pod “P”. At this point, the tweezers 35 pick up five wafers at one time. Subsequently, the tweezers 35 load the five picked up wafers into the housing 2 through the wafer loading/unloading opening 38 thereof. After the five wafers are loaded into the housing 2 by the wafer transfer unit 30, the gate 6 opens the wafer loading/unloading opening 5 of the load lock chamber 4. Subsequently, the five wafers supported by the tweezers 35 of the wafer transfer unit 30 are charged into the boat 19 by means of the wafer transfer unit 30 through the wafer loading/unloading opening 5.

Thereafter, the above-explained charging operation is repeated to move the wafers “W” from the pod “P” to the boat 19 by means of the wafer transfer unit 30. During the charging operation, the boat loading/unloading opening 11 is closed by the shutter 12, such that the antechamber 3 is protected from a high temperature condition of the process tube 15. Therefore, the wafers “W” being charged or under charging are protected from the high temperature condition, so that any adverse effect, such as a natural oxidation of the wafers “W”, resulting from the exposure to the high temperature can be prevented.

As shown in FIGS. 1 and 2, if a predetermined number of wafers “W” are charged into the boat 19, the wafer loading/unloading opening 5 is closed by the gate 6. In addition, the repair/inspection opening 7 of the load lock chamber 4 is closed by the gate 8, and the boat loading/unloading opening 11 is closed by the shutter 12. In the above-explained load lock state, the antechamber 3 is exhausted to vacuum through the exhaust line 9 and then nitrogen (N2) gas is introduced thereinto through the gas supply line 10, such that oxygen or moisture remaining therein is eliminated. Because the volume of the antechamber 3 has decreased as a result of the uplifted peripheries of the bellows-receiving portion 50, processing time for the vacuum exhaust as well as the purge gas supply is saved.

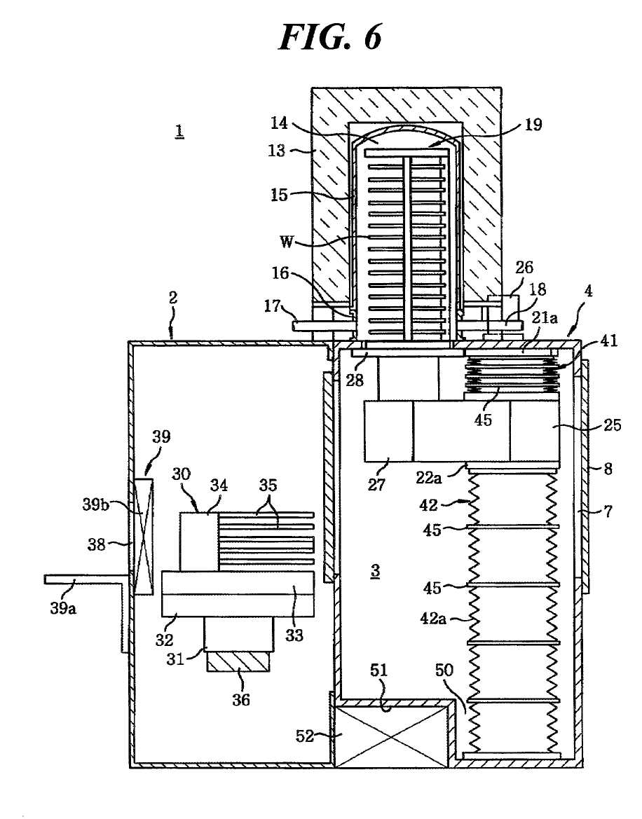

After oxygen and moisture are removed from the antechamber 3 by the vacuum exhaust and the purge gas supply, the shutter 12 opens the boat loading/unloading opening 11, as shown in FIG. 6. Subsequently, the elevator stage 25 of the boat elevator 20 elevates the boat 19 supported by the sealing cap 28, such that the boat 19 is loaded into the process chamber 14 of the process tube 15. After the boat 19 reaches the upper limit of the moving stroke of the boat 19, peripheries of an upper surface of the sealing cap 28 supporting the boat 19 airtightly closes the boat loading/unloading opening 11. Consequently, the process chamber 14 of the process pipe 15 is hermetically sealed. At this point, because oxygen or moisture is previously removed from the antechamber 3, it is ensured that the oxygen or moisture is prevented from being introduced into the process chamber 14 while the boat 19 is being loaded thereinto.

When the elevator stage 25 moves up to transfer the boat 19 into the process chamber 14, the first bellows 41 and the second bellows 42 are upwardly contracted and extended, respectively. In accordance with the present invention, because the first and the second communicating hole 43 and 44 respectively provide the atmospheric pressure to the inner spaces of the first and the second bellows 41 and 42, the upward contraction of the first bellows 41 and the upward extension of the second bellows 42 can be readily accomplished. Further, because the hollow inner spaces of the first and the second bellows 41 and 42 are hermitically isolated from the antechamber 3. Therefore, it is ensured that oxygen or moisture contained in the inner spaces of the first and the second bellows 41 and 42 is prevented from being introduced into the antechamber 3 during the above-mentioned contraction and extension, particularly, the contraction of the first bellows 41. For the same reason, a vaporized gas produced from a grease of the main guide rail 23, the screw hole 25b of the elevator stage 25, and/or the feed screw 24 is also prevented from contaminating the antechamber 3 during the above-mentioned contraction and extension of the first and the second bellows 41 and 42.

Then, the airtightly closed process chamber 14 of the process tube 15 is exhausted down to a predetermined pressure via the exhaust line 18, and then the process chamber 14 is heated up to a predetermined temperature by the heater unit 13. A process gas is subsequently introduced into the process chamber 14 at a predetermined flow rate via the gas supply line 17, thereby forming a desirable film on each wafer “W” under a preset processing condition.

After a predetermined processing time has elapsed, the elevator stage 25 of the boat elevator 20 lowers the boat 19, so that the boat 19 accommodating the processed wafers “W” is unloaded from the process chamber 14 and is returned into the antechamber 3. As previously explained, the first and the second communicating hole 43 and 44 respectively provide the atmospheric pressure to the first and the second bellows 41 and 42. Therefore, as the elevator stage 25 moves down, the downward extension of the first bellows 41 and the down contraction of the second bellows 42 can be readily accomplished.

Further as previously explained, the inner spaces of the first and the second bellows 41 and 42 are hermitically isolated from that of the antechamber 3. Therefore, it is ensured that contaminants in the inner spaces thereof are prevented from being introduced into the antechamber 3 during the above-mentioned contraction and extension, particularly, the contraction of the second bellows 42.

After the boat 19 is returned into the antechamber 3, the load lock state of the antechamber 3 is released at the same time when the shutter 12 closes the boat loading/unloading opening 11. That is to say, the gate 6 opens the wafer loading/unloading opening 5 of the antechamber 3 in such a way that the processed wafers “W” can be discharged from the boat 19 by the wafer transfer unit 30. Thereafter, the pod opener 39 opens the wafer loading/unloading opening 38 of the housing 2 as well as the cap of an empty pod “P” mounted on the loading stage 39a of the pod opener 39. Then, the processed wafers “W” discharged by the wafer transfer unit 30 are reloaded into the empty pod “P”, which is mounted on the loading stage 39a, via the wafer loading/unloading opening 38.

After a predetermined number of processed wafers “W” are reloaded into the pod “P”, the cap device 39b of the pod opener 39 restores the cap to the pod “P”. The pod “P” is subsequently conveyed from the loading stage 39a to a next process stage by the conveying system. The above-explained discharge and reload step are repeated until all the processed wafers “W” in the boat 19 are conveyed to the next process stage.

Thereafter, the above-explained operations are repeated to apply the batch process for a predetermined number of wafers, e.g., 25, 50, 100, 125, or 150 wafers “W” by means of the batch type CVD apparatus 1.

As previously explained, the inner space of the first and the second bellows 41 and 42 are separated from the antechamber 3 while communicating with the environment of the atmospheric pressure. Therefore, if the antechamber 3 is exhausted to vacuum, each of the first and the second bellows 41 and 42 may deform from its vertical or horizontal profile because of the pressure difference between the inside and the outside thereof. In the preferred embodiment, however, the horizontal reinforcing sheets 45 are vertically arranged in the first and the second bellows 41 and 42 along the main guide rail 23 or the auxiliary guide rails 49. Accordingly, the deformation of the first and the second bellows 41 and 42 is surely prevented in spite of the above-mentioned pressure difference.

In other words, because the vacuum exhaust of the antechamber 3 causes the pressure difference between the inside and the outside of each of the first and the second bellows 41 and 42, a force is radially acted on inner surfaces of the first or the second bellows 41 and 42. In spite of the radial force acted on the inner surfaces thereof, however, the vertical or horizontal profiles of the first and the second bellows 41 and 42 are prevented from being displaced since each end of the sub-bellows portion 41a and 42a is fixed to the reinforcing sheet 45, the upper installation plates 21a, 21b, or the lower installation plate 22a, 22b and, also, each reinforcing sheet 45 is guided by the main guide rail 23 and/or the auxiliary guide rails 49.

Further, because the plurality of auxiliary guide rails 49 safely guide the reinforcing sheets 45 during their elevating or descending motion, each reinforcing sheet 45 can smoothly elevate or descend without yawing. Accordingly, it is ensured that each reinforcing sheet 45 rarely affects the extension or contraction of the first and the second bellows 41 and 42. Further, because the reinforcing sheets 45 and the auxiliary guide rails 49 are disposed inside the first and the second bellows 41 and 42, it is ensured that the antechamber 3 is protected from contaminants produced by the sliding motion of the reinforcing sheets 45.

On the other hand, the number of threads of each bellows needs to be increased for a long service life, and a height of the contracted bellows is proportional to the number of the threads thereof. Since the boat reciprocates once for each batch process, the bellows used for the boat elevator extends as well as contracts once for each batch process. If it is assumed that each batch process takes about an hour, the extension/contraction number of each bellows becomes 24 in a day and reaches 42,000 after five years, for example.

Compared with that, in case that 125 wafers are processed during each batch process, though the elevator serving as the wafer transfer system of the batch type CVD apparatus carries 5 wafers at one time, the elevator reciprocates 25 times for each batch process. Therefore, the bellows for the elevator of the wafer transfer system needs 50 times longer service life than that of the boat elevator. To achieve 50 times longer service life, because the height of the maximally contracted bellows is proportional to the number of the threads, the bellows for the elevator of the wafer transfer system needs to have a 1.5 to 2 times larger maximally contracted height than that of the bellows for the boat elevator.

In other words, in case that the bellows is used for the boat elevator, the maximally contracted height of the bellows for the boat elevator can be significantly decreased in comparison to that for the elevator of the wafer transfer system while a desirable service life of the bellows for the batch type CVD apparatus is secured.

Following advantages can be provided in accordance with the above-explained embodiment of the present invention.

1) The first and the second bellows are respectively disposed on and under the elevator stage of the boat elevator installed in the antechamber. The inner spaces of the first and the second bellows individually communicate with the exterior environment of the atmospheric pressure. Therefore, even though pressure varies in the antechamber, because equal pressures are respectively acted on top and bottom of the elevator stage, driving mechanisms including the feed screw or the motor to vertically move the elevator stage of the elevator can be small-sized.

2) Because the hollow inside of the first and the second bellows individually communicate with the exterior circumstances to automatically sustain the atmospheric pressure therein, the first and the second bellows can independently contract or extend without additional pressure control devices or the like. Therefore, there is no need to install and maintain a complicated pressure control valve mechanism and a control system therefor.

3) The feed screw or the guide rail of the boat elevator is hermitically isolated from the antechamber by the first and the second bellows. Therefore, it is ensured that oxygen or moisture in the interiors of the first and the second bellows is prevented from being introduced into the antechamber during the contraction or extension of the first and the second bellows. For the same reason, a vaporized gas produced from a grease of the guide rail, the elevator stage, or the feed screw is also prevented from being introduced into the antechamber during the above-mentioned contraction and extension.

4) Because the plurality of reinforcing sheets are vertically arranged along the main guide rail or the auxiliary guide rails disposed inside the first and the second bellows, the first and the second bellows are prevented from being deformed, even though pressure differs between the inside and the outside of each of the first and the second bellows. Therefore, it is ensured that the inner spaces of the first and the second bellows can communicate with the exterior environment to automatically maintain the atmospheric pressure therein.

5) The plurality of auxiliary guide rails safely guide each reinforcing sheet, such that each reinforcing sheet can be smoothly elevated or lowered without a transversal motion, in accordance as the elevator stage elevates or descends. Therefore, each reinforcing sheet rarely affects the contraction or extension of the first and the second bellows, and it is ensured that the antechamber is protected from possible contaminants that may be produced during the sliding motion of the reinforcing sheets.

6) The bellows-receiving portion, accommodating the maximally contracted second bellows therein, is recessed at a bottom corner of the antechamber. That is, the peripheries of the bellows-receiving portion are relatively uplifted such that the inner space of the antechamber decreases by an amount corresponding to the uplifted portions. Therefore, processing time for the vacuum exhaust as well as the purge gas supply can be reduced, such that the throughput of the batch type CVD apparatus, the film forming process, and also the semiconductor fabrication method can be increased.

7) Because the boat elevator and the bellows mechanism are disposed at a corner region of the antechamber, a wasted area of the batch type CVD apparatus can be reduced. Further, because the inner space of the antechamber is also reduced, processing time required for the vacuum exhaust and the purge gas supply can be reduced. As a result, the throughput of the batch type CVD apparatus, the film forming process, and also the semiconductor fabricating method can be increased.

In the preferred embodiment of the present invention, the bellows-receiving portion has been described as being provided at the bottom of the antechamber. The bellows-receiving portion, however, may be alternatively formed at the upper region of the antechamber, or two of them may be provided at the bottom and the upper region thereof, respectively.

The bellows is selected for each of the first and the second expendable/contractible structure, each having the inner space, in accordance with the preferred embodiment of the present invention. Instead of adopting the bellows, however, the first or the second extendable/contractible structure may have a bag-like shape made of a thin wall having appropriate strength and flexibility. Further, the first or the second extendable/contractible structure may have a telescope-like shape, where a plurality of tubes are telescopically connected or nested with each other.

The batch type CVD apparatus described above can be employed in not only to the film forming process but also to an oxidation process or a diffusion process. Though the preferred embodiment has been described with respect to the batch type CVD apparatus, the present invention also can be applied to other types of the substrate processing apparatus.

While the invention has been shown and described with respect to the preferred embodiments, it will be understood to those skilled in the art that various changes and modifications may be made without departing from the spirit and scope of the invention as defined in the following claims.

What is claimed is:

1. A substrate processing apparatus comprising:
a process chamber for processing substrates;
a sealed chamber arranged adjacent to the process chamber;
a movable member, disposed inside the sealed chamber, for supporting the substrates;
an extendable/contractible structure including a first extendable/contractible member and a second extendable/contractible member respectively disposed on both opposing sides of the movable member, wherein interiors of the first and the second extendable/contractible member communicate with an exterior of the sealed chamber; and
a driving means, disposed in the extendable/contractible structure, for moving the movable member, wherein the driving means is isolated from an inner space of the sealed chamber by the extendable/contractible structure.

2. The apparatus of claim 1, wherein each of the first extendable/contractible member and the second extendable/contractible member is provided with a reinforcing member for preventing the first and the second extendable/contractible member from being deformed.

3. The apparatus of claim 1, wherein the movable member is connected to a boat accommodating the substrates, the boat being selectively loaded into and unloaded from the process chamber by the movable member.

4. The apparatus of claim 1, wherein a bellows-receiving portion is arranged in the sealed chamber, the bellows-receiving portion receiving at least one of the first extendable/contractible member and the second extendable/contractible member, each being maximally contracted.

5. The apparatus of claim 1, wherein the sealed chamber is selectively in a vacuum or in an inert gas condition.

6. The apparatus of claim 1, wherein the extendable/contractible member is arranged at a corner portion of the sealed chamber.

7. The apparatus of claim 1, wherein the extendable/contractible structure vertically extends and contracts.

8. A semiconductor device fabricating method using a substrate processing apparatus including a sealed chamber, a process chamber, and a substrate conveying unit positioned in the sealed chamber, wherein the substrate conveying unit includes a) a movable member for supporting a boat, b) a first and a second extendible/contractible member respectively disposed on both opposing sides of the movable member, interiors of the first and the second extendible/contractible member communicating with an exterior circumstance, and c) a driving means, disposed in the first and the second extendible/contractible member, for moving the movable member, the driving means being isolated from an inner space of the sealed chamber by the first and the second extendible/contractible member, the method comprising the steps of:
loading at least one substrate into the boat staying in the sealed chamber;
loading the boat into the process chamber from the sealed chamber by using the substrate conveying unit; and
processing said at least one substrate loaded in the boat.

9. A conveying unit used in a sealed chamber, the conveying unit comprising:
a movable member arranged in the sealed chamber, the movable member supporting an article;
a first extendible/contractible structure and a second extendible/contractible structure respectively disposed on both opposing sides of the movable member, wherein interiors of the first and the second extendible/contractible structure individually communicate with an exterior of the sealed chamber; and
a driving means, disposed in the first and the second extendible/contractible structure, for moving the movable member, wherein the driving means is isolated from an inner space of the sealed chamber by the first and the second extendible/contractible structure.
